(19) United States
(12) Patent Application Publication
(10) Pub. No.: US 2002/0086520 A1
(43) Pub. Date: Jul. 4, 2002

(54) Semiconductor device having bump electrode

(75) Inventor: Ching Hua Chiang, Changhua City (TW)

Correspondence Address: LOWE HAUPTMAN GOPSTEIN GILMAN & BERNER, LLP, 1700 Diagonal Road, Suite 310, Alexandria, VA, 22314, US

(73) Assignee: ADVANCED SEMICONDUCTOR ENGINEERING INC.

(21) Appl. No.: 09/750,756

(22) Filed: Jan. 2, 2001

(51) Int. Cl. H01L 21/44; H01L 21/4763

(52) U.S. Cl. 438/630

(57) ABSTRACT

A semiconductor device having a bump electrode comprising a copper contact pad on a substrate wherein at least a portion of the copper contact pad is exposed through the dielectric layer on the substrate. The copper contact pad is provided with an under bump metallurgy including a titanium layer formed on the portion of the copper contact pad, a nickel-vanadium layer formed on the titanium layer and a copper layer formed on the nickel-vanadium layer. A metal bump provided on the UBM over each copper contact pad so as to form bump electrode. The UBM of the present invention is characterized by using the nickel-vanadium layer as barrier layer thereby significantly reducing the required thickness of the titanium layer, and thereby reducing cost and enhancing reliability.

### BACKGROUND OF THE INVENTION

1. Field of the Invention

This invention relates to electronic assembly technology and more specifically to metal bump interconnections for mounting chip with copper contact pads on interconnection substrate.

2. Description of the Related Art

As chips continued to decrease in size, pure copper circuits had undeniable advantages that the traditional aluminum interconnects could not match. Copper wires conduct electricity with about 40 percent less resistance than aluminum. That translates into a speedup of as much as 15 percent in microprocessors that contain copper wires. Furthermore, copper wires are also far less vulnerable than those made of aluminum to electromigration, the movement of individual atoms through a wire, caused by high electric currents, which creates voids and ultimately breaks the wires. Most important, the widths of copper wires can be squeezed down to the 0.2-micron range from the current 0.35-micron widths—a reduction far more difficult for aluminum. Because the conventional aluminum alloys can't conduct electricity well enough, or withstand the higher current densities needed to make these circuits switch faster when wires with very small dimensions is used. Gradually, chip with copper interconnects will substitute for chip with traditional aluminum interconnects.

Besides, as electronic devices have become more smaller and thinner, the velocity and the complexity of IC chip become more and more higher. Accordingly, a need has arisen for higher package efficiency. Demand for miniaturization is the primary catalyst driving the usage of advanced packages such as chip scale packages (CSP) and flip chips. Both of them greatly reduce the amount of board real estate required when compared to the alternative ball grid array (BGA) and quad flat pack (QFP). Typically, a CSP is 20 percent larger than the die itself, while the flip chip has been described as the ultimate package precisely because it has no package. The bare die itself is attached to the substrate by means of bump electrodes directly attached to the die.

Flip-chip bumping technology typically comprises (a) forming an under bump metallurgy (UBM) on bonding pads of the chip, and (b) forming metal bumps on the UBM. Typically, UBM consists of three metal layers, including: (a) adhesion layer (formed of Al or Cr) for providing a good adhesion to Al pad and passivation layer; (b) barrier layer (formed of NiV or TiW) for preventing chip contact pad and metal bump from reacting with each other to generate an intermetallic compound (which is harmful to the reliability of chip); and (c) wetting layer (formed of Ni, Cu, Mo or Pt) wherein that kind of metals provide a higher wetting power to solder thereby allowing for proper wetting of solder during solder-reflow process. Typically, the metal bump is made of conductive material (such as metal high melting point solder alloys, low melting point solder alloys, gold, nickel or copper), depending on the characteristics needed in the to-be-formed flip-chip.

FIG. 1 is a cross sectional view of a conventional semiconductor device 100 having a bump electrode. An aluminum contact pad 110 is formed on a substrate 120 of a semiconductor integrated circuit. A passivation film 130, serving as an insulation film, is formed on the entire surface of the substrate 120. A passivation opening section which is formed at a predetermined position, is formed to expose the aluminum contact pad 110. The semiconductor device 100 has a UBM 140 consisting of three metal layers, including: (a) aluminum layer 140a (as the adhesion layer); (b) nickel-vanadium layer 140b (as the barrier layer); and (c) copper layer 140c (as the wetting layer).

However, the UBM 140 is not suitable for chip with copper contact pads because of poor aluminum-to-copper adhesion. Therefore, the semiconductor industry develops the semiconductor device 200 as shown in FIG. 2. The semiconductor device 200 has a UBM 240 consisting of two metal layers, including: (a) titanium layer 240a (as the adhesion layer and the barrier layer); (b) copper layer 240b (as the wetting layer). The titanium layer adheres well to the copper contact pad 210 and the passivation lyer 130. Typically, a plating thickness of at least 2000-4000 angstroms is necessary for the titanium layer to achieve its barrier role. However, since titanium is quite expensive, plating thickness thereof is limited. Therefore, this UBM desigh suffers a severe problem in reliability issue. Furthermore, it is very difficult to etch away titanium; hence, cycle time increase rapidly as the titanium layer become more thick when etching is involved in the manufacturing process of the semiconductor device 200.

The present invention therefore seeks to provide an under bump metallurgy which overcomes, or at least reduces the above-mentioned problems of the prior art.

### SUMMARY OF THE INVENTION

It is a primary object of the present invention to provide an under bump metallurgy adapted for chip with copper contact pads. The under bump metallurgy of the present invention is characterized by having a nickel-vanadium layer interposed between a titanium layer and a copper layer wherein the nickel-vanadium layer works as barrier layer thereby significantly reducing the required thickness of the titanium layer, and thereby reducing cost and enhancing reliability.

In order to achieve the object mentioned above, the present invention provides a semiconductor device having bump electrodes. The semiconductor device comprises copper contact pads on the substrate wherein at least a portion of each copper contact pad is exposed through a dielectric layer on the substrate. An under bump metallurgy is formed to cover on the copper contact pads. The under bump metallurgy comprises a titanium layer formed on the exposed portion of the copper contact pad, a nickel-vanadium layer formed on the titanium layer and a copper layer formed on the nickel-vanadium layer. Metal bumps are provided on the UBM over copper contact pads so as to form the bump electrodes. Consequently, the semiconductor device of the present invention can be directly mounted to a interconnection substrate by means of bump electrodes directly attached thereon.

The UBM of the present invention is characterized by using the nickel-vanadium layer as a barrier layer thereby significantly reducing the required thickness of the titanium layer to 1000-2000 angstroms, and thereby reducing cost and enhancing reliability.

The present invention further provides a method for forming a metal bump pad, the method comprising: (a) providing a copper contact pad on a substrate, at least a portion of the copper contact pad being exposed through a dielectric layer on the substrate; (b) forming a titanium layer on the portion of the copper contact pad exposed through the dielectric layer; (c) forming a nickel-vanadium layer on the titanium layer; and (d) forming a copper layer on the nickel-vanadium layer so as to form the metal bump pad.

### BRIEF DESCRIPTION OF THE DRAWINGS

Other objects, advantages, and novel features of the invention will become more apparent from the following detailed description when taken in conjunction with the accompanying drawings.

FIG. 1 is a schematic sectional view of a conventional semiconductor device having a bump electrode;

FIG. 2 is a schematic sectional view of another conventional semiconductor device having a bump electrode;

FIG. 3 is a schematic sectional view of an under bump metallurgy formed on a copper contact pad of a semiconductor device in accordance with the present invention;

FIG. 4 is a schematic sectional view of a semiconductor device having a bump electrode according to a preferred embodiment of the present invention; and

FIG. 5 is a schematic sectional view of a semiconductor device having a bump electrode according to another preferred embodiment of the present invention.

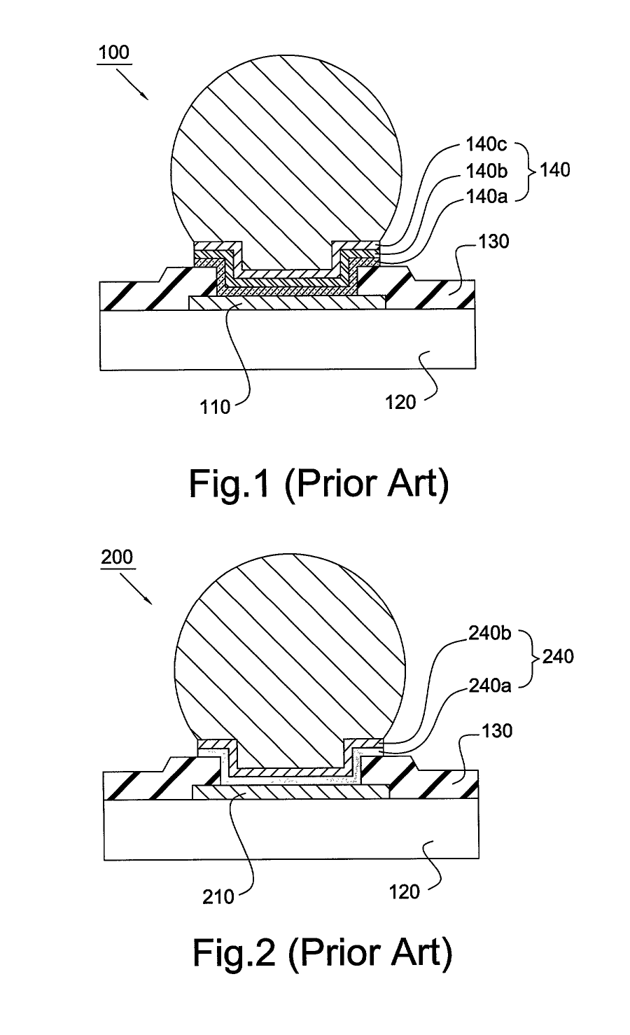

### DETAILED DESCRIPTION OF THE PREFERRED EMBODIMENT

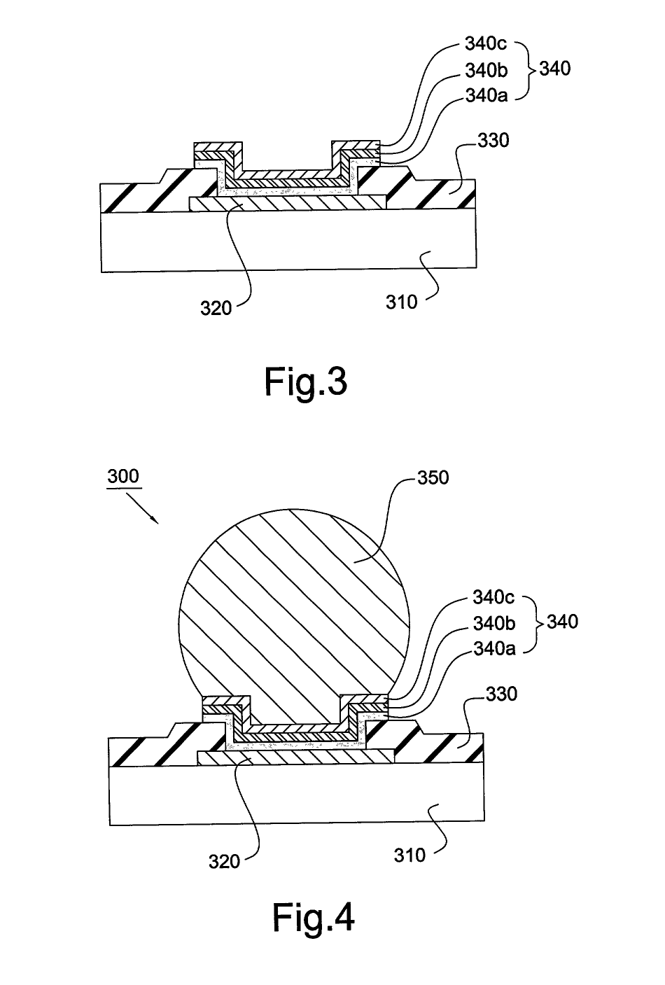

As shown in FIG. 3, a semiconductor device include a substrate 310, a copper contact pad 320, and a dielectric layer such as passivation layer 330. The substrate 310 may comprise a layer of a semiconducting material such as silicon, gallium arsenide, silicon carbide, diamond, or other substrate materials known to those having skill in the art. The passivation layer 330 is preferably a polyimide layer but can alternately be a silicon dioxide layer, a silicon nitride layer, or layers of other passivation materials known to those having skill in the art. As shown, the passivation layer 330 preferably covers the top edge portion of the copper contact pad 320 opposite the substrate, leaving the central surface portion of the copper contact pad 320.

Referring to FIG. 3, the under bump metallurgy 340 of the present invention comprises a titanium layer 340a formed on the exposed portion of the copper contact pad 330, a nickel-vanadium layer 340b formed on the titanium layer 340a and a copper layer 340c formed on the nickel-vanadium layer 340b. The UBM 340 of the present invention chooses the titanium layer 340a as adhesion layer to provide a good adhesion to the copper contact pad 320 and the passivation layer 330. Furthermore, the UBM 340 utilizing the nickel-vanadium layer 340b as a barrier layer to significantly reduce the required thickness of the titanium layer 340 thereby reducing cost and enhancing reliability. Preferably, the titanium layer 340a has a thickness ranging from about 1000 to about 2000 angstroms. The nickel-vanadium layer has a thickness ranging from about 2750 to about 3750 angstroms and the copper layer has a thickness ranging from about 7200 to about 8800 angstroms.

FIG. 4 shows a semiconductor device 300 having a solder bump 350 provided on the UBM 340 over the copper contact pad 320 to act as a bump electrode. Consequently, the semiconductor device of the present invention can be directly mounted to a interconnection substrate by means of the bump electrodes directly attached thereon. Typically, there are two kinds of solder compositions used to form the solder bump 350. They includes (a) high melting point solder alloys such as 5Sn/95Pb or 3Sn/97Pb and (b) lower melting point solder alloys such as 63Sn/37Pb or 40Sn/60Pb. Bumping process is typically accomplished by vapor deposition, electroplating or printing.

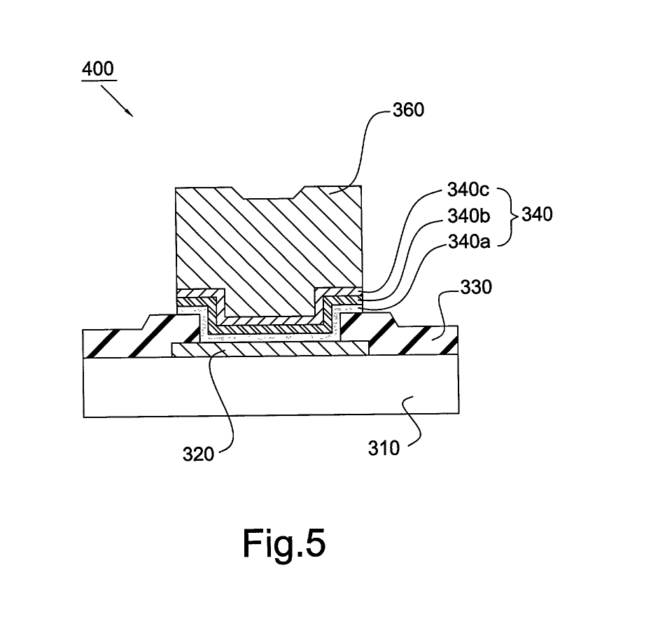

FIG. 5 shows a semiconductor device 400 having a gold bump 360 provided on the UBM 340 over the copper contact pad 320 to act as a bump electrode. Typically, the gold bump 360 comprises at least about 90 weight percentage of Au deposited on the UBM 340 by means including electroplating or evaporative lift-off,

The UBM 340 described above may be formed by an additive process for selective depositing composite layer thereof onto the copper contact pad 320. Additive processes are well known and include lift-off techniques, and the use of shadow masks.

Alternatively, the UBM 340 described above may be formed by a subtractive process. The process steps involve: (a) Sputter deposition of UBM layers (including titanium layer 340a, nickel-vanadium layer 340b and copper layer 340c) across the passivation layer and the exposed surface portions of the copper contact pads. (b) Application of photoresist and its patterning. (c) Electrodeposition of solder (or gold) on the resist opening section. (d) Stripping the photoresist and then etching the UBM layers with the plated solder (or gold) as a mask. Finally, a reflow step is proceeded if use solder to form the metal bump. Since the required thickness of the titanium layer is significantly reduced by using the nickel-vanadium layer as a barrier layer of the UBM in accordance with the present invention, cycle time of the etching step (d) is greatly decreased.

It could be understood that the semiconductor device having bump electrodes of the present invention may be formed by the following steps of: (a) Sputtering all metal layers constituting the UBM across the passivation layer 330 and the exposed surface portions of the copper contact pads; (b) selectively etching the deposited metal layers such that only the copper contact pads and the passivation layer nearby are covered with the UBM 340 (see FIG. 3); (c) printing solder onto the UBM 340 over the copper contact pads and the passivation layer nearby; and (d) reflowing.

Although the invention has been explained in relation to its preferred embodiment, it is to be understood that many other possible modifications and variations can be made without departing from the spirit and scope of the invention as hereinafter claimed.

What is claimed is:

1. A method for forming a metal bump pad, the method comprising:
providing a copper contact pad on a substrate, at least a portion of the copper contact pad being exposed through a dielectric layer on the substrate;
forming a titanium layer on the portion of the copper contact pad exposed through the dielectric layer;
forming a nickel-vanadium layer on the titanium layer; and
forming a copper layer on the nickel-vanadium layer so as to form the metal bump pad.

2. The method as claimed in claim 1, wherein the titanium layer has a thickness ranging from about 1000 to about 2000 angstroms.

3. The method as claimed in claim 2, wherein the nickel-vanadium layer has a thickness ranging from about 2750 to about 3750 angstroms and the copper layer has a thickness ranging from about 7200 to about 8800 angstroms.

4. The method as claim in claim 1, wherein the dielectric layer is a passivation layer.

5. A semiconductor device having a bump electrode comprising:
a substrate having a dielectric layer formed thereon;
a copper contact pad on the substrate wherein at least a portion of the copper contact pad is exposed through the dielectric layer on the substrate;
a titanium layer formed on the portion of the copper contact pad;
a nickel-vanadium layer formed on the titanium layer;
a copper layer formed on the nickel-vanadium layer; and
a metal bump provided on the copper layer.

6. The semiconductor device as claimed in claim 5, wherein the titanium layer has a thickness ranging from about 1000 to about 2000 angstroms.

7. The semiconductor device as claimed in claim 6, wherein the nickel-vanadium layer has a thickness ranging from about 2750 to about 3750 angstroms and the copper layer has a thickness ranging from about 7200 to about 8800 angstroms.

8. The semiconductor device as claimed in claim 5, wherein the dielectric layer is a passivation layer.

9. The semiconductor device as claimed in claim 5, wherein the metal bump is a gold bump.

10. The semiconductor device as claimed in claim 5, wherein the metal bump is a solder bump.
